(19) United States
(12) Patent Application Publication
(10) Pub. No.: US 2011/0020752 A1
(43) Pub. Date: Jan. 27, 2011

(54) EXTREME ULTRAVIOLET RADIATION SOURCE AND METHOD FOR PRODUCING EXTREME ULTRAVIOLET RADIATION

(75) Inventors: Yurii Victorovitch Sidelnikov, Moscow Region (RU); Vadim Yevgenyevich Banine, Deurne (NL); Konstantin Nikolaevich Koshelev, Moscow Region (RU); Vladimir Mihailovitch Krivtsun, Moscow Region (RU)

Correspondence Address: PILLSBURY WINTHROP SHAW PITTMAN, LLP, P.O. BOX 10500, MCLEAN, VA, 22102, US

(73) Assignee: ASML NETHERLANDS B.V., Veldhoven (NL)

(21) Appl. No.: 12/810,636

(22) PCT Filed: Dec. 19, 2008
(86) PCT No.: PCT/EP2008/010886

§ 371 Date: Oct. 8, 2010

Related U.S. Application Data
(60) Provisional application No. 61/009,193, filed on Dec. 27, 2007.

(51) Int. Cl. G03F 7/20; H05G 2/00; G03B 27/54

(52) U.S. Cl. 430/311; 250/504 R; 355/67

(57) ABSTRACT

A radiation source is constructed and arranged to produce extreme ultraviolet radiation. The radiation source includes a chamber, a first electrode at least partially contained in the chamber, a second electrode at least partially contained in the chamber, and a supply constructed and arranged to provide a discharge gas to the chamber. The first electrode and the second electrode are configured to create a discharge in the discharge gas to form a plasma so as to generate the extreme ultraviolet radiation. The source also includes a gas supply constructed and arranged to provide a gas at a partial pressure between about 1 Pa and about 10 Pa at a location near the discharge. The gas is selected from the group consisting of hydrogen, helium, and a mixture of hydrogen and helium.

### CROSS-REFERENCE TO RELATED APPLICATIONS

This application claims the benefit of U.S. provisional application 61/009,193, which was filed on 27 Dec. 2007, and which is incorporated herein in its entirety by reference.

### FIELD

The present invention relates to a lithographic apparatus and a method for producing extreme ultraviolet radiation.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g. comprising part of, one, or several dies) on a substrate (e.g. a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{{NA}_{PS}} \qquad ( 1 )$$

where λ is the wavelength of the radiation used, NA_{PS} is the numerical aperture of the projection system used to print the pattern, k₁ is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA_{PS} or by decreasing the value of k₁.

In order to shorten the exposure wavelength and, thus, reduce the minimum printable size, it has been proposed to use an extreme ultraviolet (EUV) radiation source. EUV radiation sources are configured to output a radiation wavelength of about 13 nm. Thus, EUV radiation sources may constitute a significant step toward achieving small features printing. Such radiation is termed extreme ultraviolet or soft x-ray, and possible sources include, for example, laser-produced plasma sources, discharge plasma sources, or synchrotron radiation from electron storage rings.

When using a discharge plasma source, particle radiation is created as a by-product of the EUV radiation. Generally, such particle radiation is considered to be undesired, because particles of which the particle radiation consists may inflict damage on parts of the lithographic apparatus, most notably mirrors which are located in a vicinity of the plasma source.

In order to mitigate the damage inflicted by the particle radiation it has been proposed in U.S. Pat. No. 7,026,629 to provide a buffer gas in a space separated from the discharge plasma source by a wall.

### SUMMARY

It is desirable to further mitigate the damage inflicted by the particle radiation.

according to an aspect of the present invention, there is provided a radiation source that is constructed and arranged to produce extreme ultraviolet radiation. The radiation source includes a chamber, a first electrode at least partially contained in the chamber, a second electrode at least partially contained in the chamber, and a supply constructed and arranged to provide a discharge gas to the chamber. The first electrode and the second electrode are configured to create a discharge in the discharge gas to form a plasma so as to generate the extreme ultraviolet radiation. The source also includes a gas supply constructed and arranged to provide a gas at a partial pressure between about 1 Pa and about 10 Pa at a location near the discharge. The gas is selected from the group consisting of hydrogen, helium, and a mixture of hydrogen and helium. The gas supply may be constructed and arranged to provide the gas at a partial pressure between about 2 Pa and about 9 Pa, between about 3.5 Pa and about 7 Pa or even between about 4 Pa and about 6 Pa at said location.

Preferably, the source comprises a collector configured to focus the extreme ultraviolet radiation in an intermediate focus.

According to an aspect of the present invention, there is provided a lithographic apparatus that includes a radiation source that is constructed and arranged to produce extreme ultraviolet radiation. The radiation source includes a chamber, a first electrode at least partially contained in the chamber, a second electrode at least partially contained in the chamber, and a supply constructed and arranged to provide a discharge gas to the chamber. The first electrode and the second electrode are configured to create a discharge in the discharge gas to form a plasma so as to generate the extreme ultraviolet radiation. The source also includes a gas supply constructed and arranged to provide a gas at a partial pressure between about 1 Pa and about 10 Pa at a location near the discharge. The gas is selected from the group consisting of hydrogen, helium, and a mixture of hydrogen and helium. Again, the partial pressure may be anywhere between about 2 Pa and about 9 Pa, between about 3.5 Pa and about 7 Pa or even between about 4 Pa and about 6 Pa at said location.

According to an aspect of the present invention, there is provided a method for producing extreme ultraviolet radiation. The method includes providing a discharge gas to a chamber comprising a first electrode and a second electrode, and applying a voltage to the first electrode and the second electrode to create a discharge in the discharge gas. The discharge forms a plasma which emits extreme ultraviolet radiation. The method also includes maintaining a gas at a partial pressure between about 1.5 Pa and about 10 Pa at a location near the discharge, the gas being selected from the group consisting of hydrogen, helium, and a mixture of hydrogen and helium.

According to an aspect of the present invention, there is provided a device manufacturing method that includes providing a discharge gas to a chamber comprising a first electrode and a second electrode, and applying a voltage to the first electrode and the second electrode to create a discharge in the discharge gas. The discharge forms a plasma which emits extreme ultraviolet radiation. The method also includes maintaining a gas at a partial pressure between about 1.5 Pa and about 10 Pa at a location near the discharge. The gas is selected from the group consisting of hydrogen, helium, and a mixture of hydrogen and helium. The method further includes converting the extreme ultraviolet radiation into a beam of radiation, patterning the beam of radiation, and projecting the patterned beam of radiation onto a target portion of a substrate.

### BRIEF DESCRIPTION OF THE DRAWINGS

Embodiments of the invention will now be described, by way of example only, with reference to the accompanying schematic drawings in which corresponding reference symbols indicate corresponding parts, and in which:

FIG. 1 depicts a lithographic apparatus according to an embodiment of the invention;

FIG. 2a is a schematic top view of a source according to an embodiment of the invention;

FIG. 2b is a front view along the line A-A′ of a part of a trapping device used in the source of FIG. 2a;

FIG. 2c is a schematic side view of the source of FIG. 2a;

FIG. 3a depicts an embodiment of a grazing incidence collector;

FIG. 3b depicts an embodiment of a normal incidence collector;

FIG. 3c depicts an embodiment of a Schwarzschild collector; and

FIG. 4 depicts a schematic top view of a source according to an embodiment of the invention.

### DETAILED DESCRIPTION

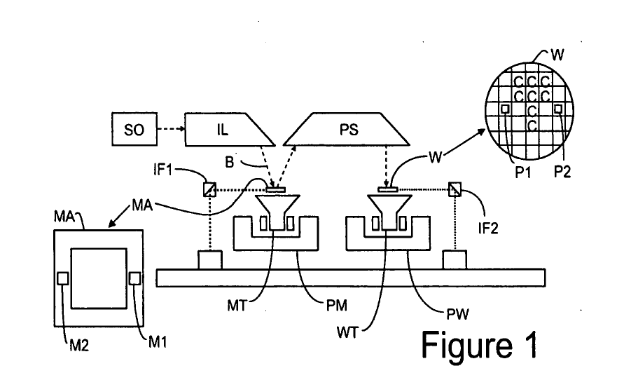

FIG. 1 schematically depicts a lithographic apparatus according to an embodiment of the invention. The apparatus comprises an illumination system (illuminator) IL configured to condition a radiation beam B (e.g. EUV radiation); a support structure (e.g. a mask table) MT constructed to support a patterning device (e.g. a mask or a reticle) MA and connected to a first positioner PM configured to accurately position the patterning device; a substrate table (e.g. a wafer table) WT constructed to hold a substrate (e.g. a resist-coated wafer) W and connected to a second positioner PW configured to accurately position the substrate; and a projection system (e.g. a reflective projection lens system) PS configured to project a pattern imparted to the radiation beam B by patterning device MA onto a target portion C (e.g. comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure holds the patterning device in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The term “projection system” may encompass any type of projection system, including refractive, reflective, catadioptric, magnetic, electromagnetic and electrostatic optical systems, or any combination thereof, as appropriate for the exposure radiation being used, or for other factors such as the use of an immersion liquid or the use of a vacuum. It may be necessary to use a vacuum for EUV or electron beam radiation since other gases may absorb too much radiation or electrons. A vacuum environment may therefore be provided to the whole beam path with the aid of a vacuum wall and vacuum pumps.

As here depicted, the apparatus is of a reflective type (e.g. employing a reflective mask). Alternatively, the apparatus may be of a transmissive type (e.g. employing a transmissive mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives a radiation beam from a radiation source SO. The source and the lithographic apparatus may be separate entities, for example when the source is an excimer laser. In such cases, the source is not considered to form part of the lithographic apparatus and the radiation beam is passed from the source SO to the illuminator IL with the aid of a beam delivery system comprising, for example, suitable directing mirrors and/or a beam expander. In other cases the source may be an integral part of the lithographic apparatus, for example when the source is a mercury lamp. The source SO and the illuminator IL, together with the beam delivery system if required, may be referred to as a radiation system.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as an integrator and a condenser. The illuminator may be used to condition the radiation beam, to have a desired uniformity and intensity distribution in its cross-section.

The radiation beam B is incident on the patterning device (e.g., mask MA), which is held on the support structure (e.g., mask table MT), and is patterned by the patterning device. After being reflected from the patterning device (e.g. mask MA), the radiation beam B passes through the projection system PS, which focuses the beam onto a target portion C of the substrate W. With the aid of the second positioner PW and position sensor IF2 (e.g. an interferometric device, linear encoder or capacitive sensor), the substrate table WT can be moved accurately, e.g. so as to position different target portions C in the path of the radiation beam B. Similarly, the first positioner PM and another position sensor IF1 can be used to accurately position the mask MA with respect to the path of the radiation beam B. Mask MA and substrate W may be aligned using mask alignment marks M1, M2 and substrate alignment marks P1, P2.

The depicted apparatus could be used in at least one of the following modes:

1. In step mode, the mask table MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.

2. In scan mode, the mask table MT and the substrate table WT are scanned synchronously while a pattern imparted to the radiation beam is projected onto a target portion C (i.e. a single dynamic exposure). The velocity and direction of the substrate table WT relative to the support structure (e.g. mask table MT) may be determined by the (de-)magnification and image reversal characteristics of the projection system PS.

3. In another mode, the support structure (e.g. mask table MT) is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes programmable patterning device, such as a programmable mirror array of a type as referred to above.

Combinations and/or variations on the above described modes of use or entirely different modes of use may also be employed.

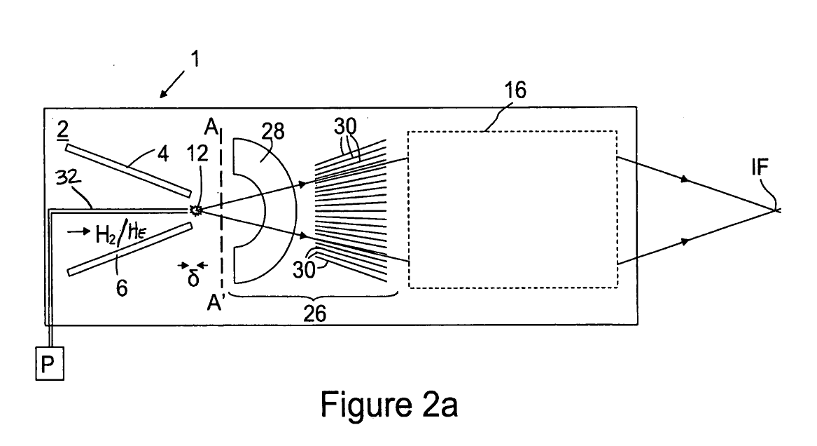

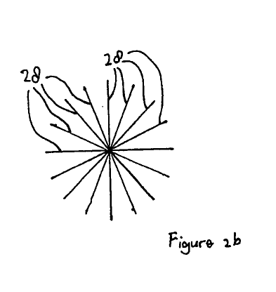

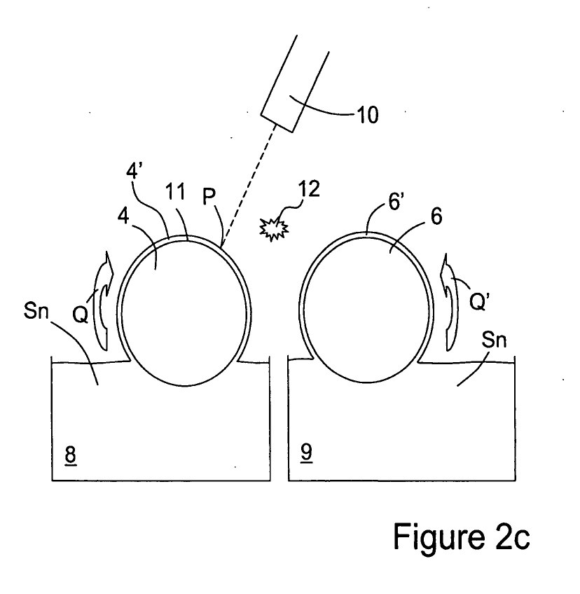

FIGS. 2a-2c illustrate a module comprising a source 1 constructed and arranged to produce extreme ultraviolet (EUV) radiation. The source 1 is provided with a chamber 2 in which a first electrode 4 and a second electrode 6 may be at least partially contained. The electrodes 4, 6 may be wheel-shaped and rotatable around respective axes as shown in FIG. 2c. The source 1 may also comprise a supply formed by two baths 8, 9 (also shown in FIG. 2c) which may each comprise liquid tin Sn which makes contact with each of the electrodes 4, 6. Instead of tin, another material may be used, such as lithium. The source 1 is further provided with a laser 10 constructed and arranged to irradiate one of the electrodes 4 at a position P on a surface 11 on the electrode 4.

When the source is in operation, a voltage is applied to the electrodes 4, 6. The electrodes 4, 6 may rotate, for instance in respective directions Q and Q′ as shown in FIG. 2c. Due to the rotation, the electrodes 4, 6 may be constantly cooled by their respective baths 8, 9. The tin in the baths 8, 9 sticks to the electrodes 4, 6 thereby forming a film 4′, 6′ on each of the electrodes 4, 6. In FIG. 2c, it is shown that for one electrode 4, the rotation causes liquid tin sticking to the electrodes to be brought to the position P where the tin is irradiated by the laser 10. The liquid tin irradiated by the laser 10 provides a discharge gas to the chamber 2. Due to the voltage on the two mentioned electrodes 4, 6, a discharge is created in the discharge gas. From the discharge, plasma is created in a so-called pinch 12 which produces EUV radiation.

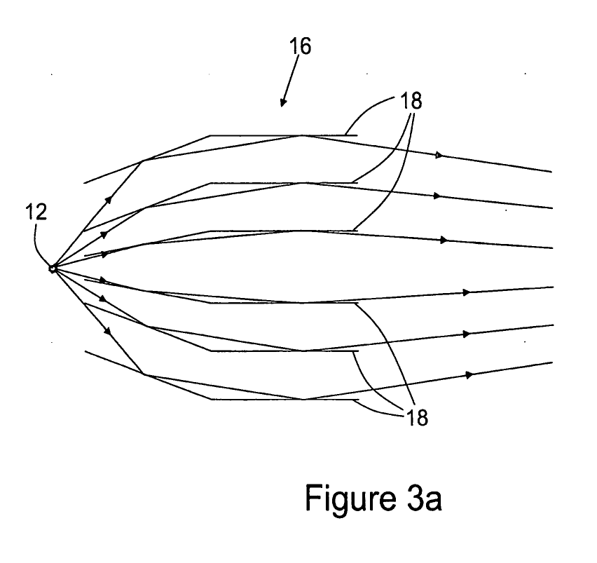

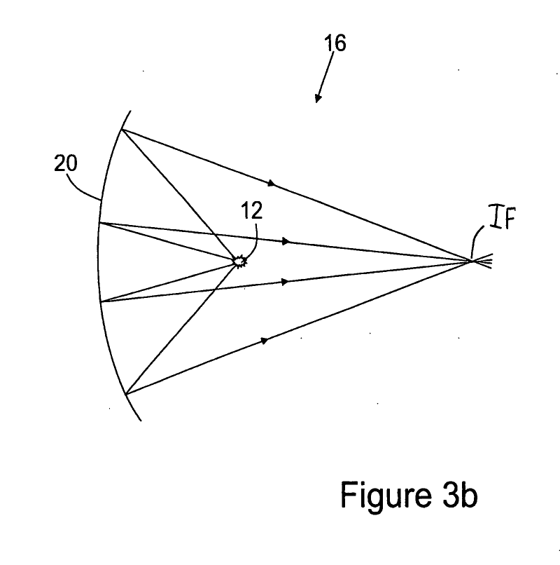

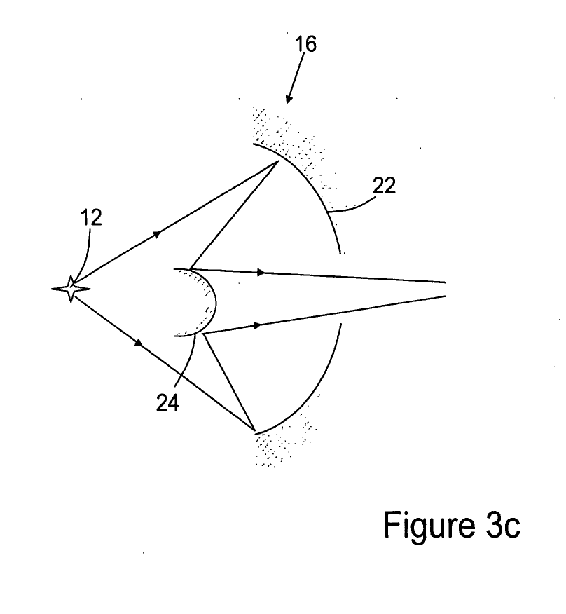

The source 1 may comprise a collector 16 which is constructed and arranged to focus the EUV radiation produced at the pinch 12 in an intermediate focus IF. Such a collector 16 may be contained inside the chamber 2. Examples of collectors 16 are shown in FIGS. 3a-c. However, a person skilled in the art will appreciate that collectors other than the examples shown in FIGS. 3a-c may be suitable in the lithographic apparatus.

FIG. 3a depicts a collector 16 which is formed by a plurality of shell-formed mirrors 18 co-axially arranged with respect to each other and constructed and arranged to reflect the EUV radiation under a grazing angle.

FIG. 3b depicts a collector 16 which is formed by a single normal-incidence mirror 20. The mirror 20 is located such that the plasma which produces the EUV radiation is located between the mirror 20 and the intermediate focus IF.

FIG. 3c depicts a collector 16 which is commonly referred to as a Schwarzschild collector 16. The collector comprises a first mirror 22, second mirror 24.

In addition to EUV radiation which is used to form the radiation beam which may be received and conditioned by the illuminator IL, the pinch 12 and the electrodes 4, 6 may produce significant quantities of particle debris which may impact on any optics located downstream along the optical path of the EUV radiation beam, especially the collector 16.

In order to mitigate the damage incurred on the collector 16 by the particle radiation, it has been proposed to construct a trapping device to intercept the particles using a plurality of blades which are aligned with the location of the plasma in order to ensure as much transmission of the EUV radiation as possible.

A possible configuration of such a trapping device is depicted in FIGS. 2a and 2b. In FIG. 2a it can be seen that a first part of the trapping device 26 comprises a plurality of blades 28 (shown in more detail in FIG. 2b). The blades 28 are preferably aligned with the pinch 12 in order to allow EUV radiation produced to be transmitted. However, the blades 28 are dimensioned and positioned such that any particles emitted from the first electrode 4 and/or the second electrode 6 may be intercepted by at least one of the blades 28.

Instead of or in addition to the first part of the trapping device 26, the trapping device 26 may include a second part comprising a plurality of stationary lamellas 30 (FIG. 2a). Each of these lamellas may be aligned with the pinch 12. The lamellas 30 may be positioned and dimensioned such that, despite not obstructing any radiation emitted from the pinch 12, they trap any debris emitted from the electrodes 4 and 6.

In order to be able to intercept any particles emitted from the pinch 12, the blades 28 may be rotatably arranged in order to allow the blades 28 to move in directions transverse to movement directions of the particles emitted from the pinch 12, thereby allowing them to intercept the particles emitted from the pinch 12.

The source 1 of FIG. 2a comprises a supply 32 that may include a pumping device P. The supply 32 is constructed and arranged to provide hydrogen and/or helium to the chamber 2. In the embodiment of FIG. 2 the supply is located near the location of the pinch 12 at a distance δ. The distance δ may have a value of about 3 cm. However, other values for the distance δ, for instance a value for the distance δ of about 5 cm or a value for the distance δ of about 1 cm, may also be suitable.

The supply 32 may be configured such that at the location near the location of the pinch 12, hydrogen and/or helium may be present at a partial pressure of between about 1 Pa and about 10 Pa, or between about 1.5 Pa and about 10 Pa, or between about 2 Pa and about 9 Pa, or between about 3.5 Pa and about 7 Pa, or between about 4 Pa and about 6 Pa, or about 5 Pa. However, other suitable pressures outside these ranges may be applied.

A person skilled in the art would expect that this presence of hydrogen and/or helium would have negative consequences on the conversion efficiency, because at least any discharge between the electrodes 4, 6, would occur through materials other than the discharge gas which is tin in this example.

Surprisingly, any negative influence on conversion efficiency and thus to the power of the EUV radiation source SO has been found to be limited. Moreover, it has been shown that providing the hydrogen, helium or a mixture thereof near the pinch 12 at a partial pressure between about 1 Pa and about 10 Pa may have a particular advantageous effect on the amount of debris emitted from the pinch 12.

The presence of hydrogen and/or helium at the location near the discharge should not be construed to mean that the hydrogen is present at a predetermined pressure throughout the chamber 2. Another gas may be provided at another location. For instance, argon may be supplied to a location between the plurality of blades 28 of the first part and the plurality of the lamellas 30 of the second part of the trapping device 28.

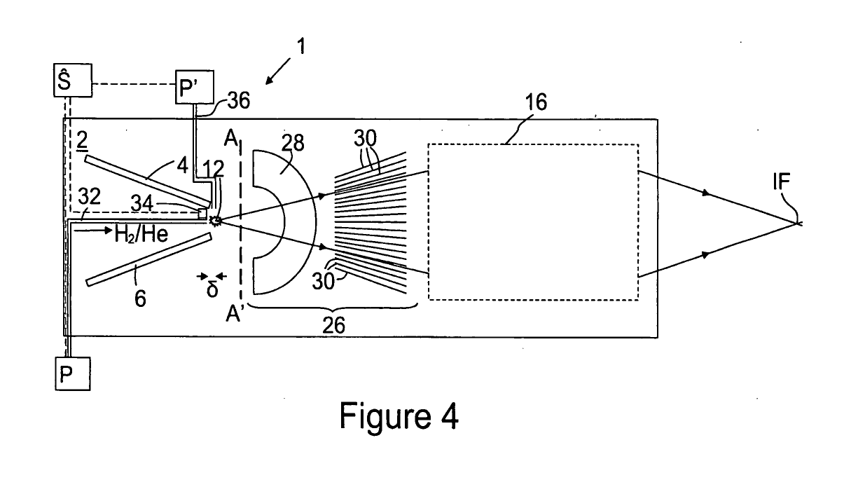

An embodiment of the source 1 is shown in FIG. 4. This embodiment is quite similar to the embodiment depicted in FIG. 2a. The embodiment of FIG. 4 may comprise a pressure sensor 34 that is configured and arranged to measure the partial pressure of hydrogen, helium or mixture thereof, an outlet 36 and a further pumping device P′ constructed and arranged to pump gas away from a location near the discharge through the outlet 36. Moreover, this embodiment comprises a pressure control Ŝ configured to control both pumping devices P, P′ so as to maintain the partial pressure of the hydrogen, helium or mixture thereof at a predetermined partial pressure based on measurements of the pressure sensor 34.

In operation, the sensor 34 measures partial pressure of the hydrogen, helium or mixture thereof. If the sensor 34 measures a partial pressure that is too low, the pressure control Ŝ may increase the pumping power of pumping device P and/or decrease the pumping power of pumping device P′. As a consequence, the partial pressure may rise to a suitable level.

On the other hand, if the sensor 34 measures a partial pressure that is too high, the pressure control Ŝ may decrease the pumping power of pumping device P and/or increase the pumping power of pumping device P′. As a consequence, the partial pressure may drop to a suitable level.

A suitable partial pressure range to maintain the partial pressure of the gas selected from the group consisting of hydrogen, helium or a mixture thereof may be between about 1 Pa and about 10 Pa, or between about 1.5 Pa and about 10 Pa, or between about 2 Pa and about 9 Pa, or between about 3.5 Pa and about 7 Pa, or between about 4 Pa and about 6 Pa, or about 5 Pa at the location near the pinch 12.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, etc.

Although specific reference may have been made above to the use of embodiments of the invention in the context of optical lithography, it will be appreciated that the invention may be used in other applications, for example imprint lithography, and where the context allows, is not limited to optical lithography.

The terms “radiation” and “beam” used herein encompass all types of electromagnetic radiation, including ultraviolet (UV) radiation (e.g. having a wavelength of or about 365, 355, 248, 193, 157 or 126 nm) and extreme ultra-violet (EUV) radiation (e.g. having a wavelength in the range of 5-20 nm), as well as particle beams, such as ion beams or electron beams.

While specific embodiments of the invention have been described above, it will be appreciated that the invention may be practiced otherwise than as described. For example, the invention may take the form of a computer program containing one or more sequences of machine-readable instructions describing a method as disclosed above, or a data storage medium (e.g. semiconductor memory, magnetic or optical disk) having such a computer program stored therein.

The descriptions above are intended to be illustrative, not limiting. Thus, it will be apparent to one skilled in the art that modifications may be made to the invention as described without departing from the scope of the claims set out below.

1. A radiation source constructed and arranged to produce extreme ultraviolet radiation, the radiation source comprising:
a chamber;
a first electrode at least partially contained in the chamber;
a second electrode at least partially contained in the chamber;
a supply constructed and arranged to provide a discharge gas to the chamber, the first electrode and the second electrode being configured to create a discharge in the discharge gas to form a plasma so as to generate the extreme ultraviolet radiation; and
a gas supply constructed and arranged to provide a gas at a partial pressure between about 1 Pa and about 10 Pa at a location near the discharge, the gas being selected from the group consisting of hydrogen, helium, and a mixture of hydrogen and helium.

2. A radiation source according to claim 1, further comprising a pressure sensor and a pressure control configured to control the gas supply so as to maintain a preset gas pressure.

3. A radiation source according to claim 1, wherein the partial pressure is located at a position within a distance of about 5 cm of the location of the discharge.

4. A radiation source according to claim 3, wherein the partial pressure is located at a position within a distance of about 1 cm of the location of the discharge.

5. A lithographic apparatus, comprising:
a radiation source constructed and arranged to produce extreme ultraviolet radiation, the radiation source comprising
a chamber,
a first electrode at least partially contained in the chamber,
a second electrode at least partially contained in the chamber,
a supply constructed and arranged to provide a discharge gas to the chamber, the first electrode and the second electrode being configured to create a discharge in the discharge gas to form a plasma so as to generate the extreme ultraviolet radiation, and
a gas supply constructed and arranged to provide a gas at a partial pressure between about 1 Pa and about 10 Pa at a location near the discharge, the gas being selected from the group consisting of hydrogen, helium, and a mixture of hydrogen and helium.

6. A lithographic apparatus according to claim 5, further comprising:
a support constructed and arranged to support a patterning device, the patterning device being capable of imparting a radiation beam with a pattern in its cross-section to form a patterned radiation beam;
a substrate table constructed and arranged to hold a substrate;
an illumination system configured to convert the extreme ultraviolet radiation into the radiation beam and to direct the radiation beam to the patterning device; and
a projection system configured to project the patterned radiation beam onto a target portion of the substrate.

7. A method for producing extreme ultraviolet radiation, the method comprising:
providing a discharge gas to a chamber comprising a first electrode and a second electrode;
applying a voltage to the first electrode and the second electrode to create a discharge in the discharge gas, the discharge forming a plasma which emits extreme ultraviolet radiation; and
maintaining a gas at a partial pressure between about 1.5 Pa and about 10 Pa at a location near the discharge, the gas being selected from the group consisting of hydrogen, helium, and a mixture of hydrogen and helium.

8. A method according to claim 7, wherein the partial pressure maintained at said location is between about 2 Pa and about 9 Pa.

9. A method according to claim 8, wherein the partial pressure maintained at said location is between about 3.5 Pa and about 7 Pa.

10. A method according to claim 9, wherein the partial pressure maintained at said location is between about 4 Pa and about 6 Pa.

11. A method according to claim 7, wherein hydrogen is supplied to the chamber in order to maintain the hydrogen pressure within said pressure range.

12. A method according to claim 7, wherein hydrogen is evacuated from the chamber in order to maintain the hydrogen pressure within said pressure range.

13. A method according to claim 7, wherein the partial pressure is located at a position within a distance of about 5 cm of the location of the discharge.

14. A method according to claim 13, wherein the partial pressure is located at a position within a distance of about 1 cm of a location of the discharge.

15. A device manufacturing method, comprising:
providing a discharge gas to a chamber comprising a first electrode and a second electrode;
applying a voltage to the first electrode and the second electrode to create a discharge in the discharge gas, the discharge forming a plasma which emits extreme ultraviolet radiation;
maintaining a gas at a partial pressure between about 1.5 Pa and about 10 Pa at a location near the discharge, the gas being selected from the group consisting of hydrogen, helium, and a mixture of hydrogen and helium;
converting the extreme ultraviolet radiation into a beam of radiation;
patterning the beam of radiation; and
projecting the patterned beam of radiation onto a target portion of a substrate.
